(19) United States
(12) Patent Application Publication
(10) Pub. No.: US 2009/0316375 A1
(43) Pub. Date: Dec. 24, 2009

(54) Electronic circuit board including surface mount device

(75) Inventor: Kouji Ueda, Kariya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/457,219

(22) Filed: Jun. 4, 2009

(30) Foreign Application Priority Data
Jun. 23, 2008 (JP) 2008-163837
Jul. 15, 2008 (JP) 2008-184204
Jan. 19, 2009 (JP) 2009-9145

(51) Int. Cl. H05K 7/06; H05K 3/34

(52) U.S. Cl. 361/768; 29/840

(57) ABSTRACT

An electronic circuit board includes a substrate, a plurality of devices mounted on the substrate, and a pattern part disposed on a surface of the substrate. The devices include a surface mount device having a heat capacity higher than other device. The surface mount device includes a terminal part. The pattern part has an area larger than a pattern area determined in accordance with a current capacity for securing a required current value to be supplied to the surface mount device. The pattern part includes a land part to which the terminal part of the surface mount device is coupled with a solder melted by heating in a reflow furnace.

### CROSS REFERENCE TO RELATED APPLICATIONS

The present application is based on and claims priority to Japanese Patent Applications No. 2008-163837 filed on Jun. 23, 2008, No. 2008-184204 filed on Jul. 15, 2008, and No. 2009-9145 filed on Jan. 19, 2009, the contents of which are incorporated in their entirety herein by reference.

### BACKGROUND OF THE INVENTION

1. Field of the Invention

The present invention relates to an electronic circuit board including a surface mount device.

2. Description of the Related Art

In a diesel engine and a direct fuel-injection engine, a high responsiveness of opening and closing a valve of an injector is required for injecting minute fuel with a high degree of accuracy. Thus, an injector driving circuit includes a DC-DC converter as a boost circuit for boosting a battery voltage and a capacitor for storing the voltage boosted by the DC-DC converter as described, for example, in JP-A-2000-110640. Before activating a transistor for driving the injector, the capacitor is charged by the DC-DC converter. When the transistor is activated, a high current supplies from the capacitor to the injector. Thus, when the valve of the injector is opened, the valve can be opened with a high velocity.

It is required for stably supplying the high current to the injector even if a discharge frequency from the capacitor increases, for example, when a rotation speed of the engine increases. Thus, the DC-DC converter is required to have a power choke coil being difficult to be saturated magnetically and having a high inductance. In addition, as a capacitor for supplying a driving current to the injector, a high-capacity capacitor being capable of storing a high energy is used.

The power choke coil and a high-capacity capacitor respectively becomes a large device. Such a large device may be configured as a through-hole mount device (THD) so that a mounting state and an electric connection to a substrate can be maintained with certainty even in severe environmental conditions such as a temperature change and a vibration.

However, the through-hole mount device cannot be mounted on a rear surface of the substrate and a pattern cannot be arranged in a middle layer of the substrate. Thus, a dimension of a product is difficult to be reduced. In view of such circumstances, the large device such as the power choke coil may be configured as a surface mount device (SMD).

When the large component such as the power choke coil is configured as the surface mount device, a heat capacity is high because the dimension is large and because the power choke coil is made of a core and a winding. Thus, when a terminal of the surface mount device is soldered with a land of the substrate by a reflow heating, a temperature of the terminal is difficult to be increased. As a result, a reduction in a quality of soldering including insufficient solder wettability and insufficient solder melting may occur. Such issue arises especially when a solder having a high melting point, such as, for example, a lead-free solder is used.

Although above-described issue may be solved by locally heating the circuit board on which the surface mount device is disposed and increasing a heating time, another issue such as an increasing of a production cost and an increasing of a thermal stress to other device may arise.

### SUMMARY OF THE INVENTION

In view of the foregoing problems, it is an object of the present invention to provide an electronic circuit board that can restrict a reduction in a quality of soldering even if a terminal of a surface mount device is soldered with a substrate by a reflow heating.

An electronic circuit board according to an aspect of the present invention includes a substrate, a plurality of devices mounted on the substrate, and a pattern part disposed on a surface of the substrate. The devices include a surface mount device having a heat capacity higher than other device. The surface mount device includes a terminal part. The pattern part has an area larger than a pattern area determined in accordance with a current capacity for securing a required current value to be supplied to the surface mount device. The pattern part includes a land part to which the terminal part of the surface mount device is coupled with a solder melted by heating in a reflow furnace.

In the present electronic circuit board, a reduction in quality of soldering can be restricted even if the surface mount device having the high heat capacity is soldered to the substrate by a reflow heating.

### BRIEF DESCRIPTION OF THE DRAWINGS

Additional objects and advantages of the present invention will be more readily apparent from the following detailed description of exemplary,embodiments when taken together with the accompanying drawings. In the drawings:

FIG. 1 a diagram illustrating an exemplary configuration of a boost circuit used for an injector driving circuit;

FIG. 2 is a diagram illustrating a perspective view of an electronic circuit board according to a first embodiment of the present invention carried in a reflow furnace;

FIG. 3 is a diagram illustrating a wiring pattern in a surface wiring layer of the electronic circuit board;

FIG. 4 is a diagram illustrating a mounting surface of a surface mount device and lands;

FIG. 5 is a diagram illustrating a soldering state of a connecter terminal and one of the lands;

FIG. 6 is a diagram illustrating a perspective view of an electronic circuit board according to a second embodiment of the present invention carried in a reflow furnace;

FIG. 7 is a diagram illustrating a perspective view of an electronic circuit board according to a third embodiment of the present invention carried in a reflow furnace;

FIG. 8 is a diagram illustrating a perspective view of an electronic circuit board according to a fourth embodiment of the present invention carried in a reflow furnace;

FIG. 9 is a diagram illustrating a perspective view of an electronic circuit board according to a fifth embodiment of the present invention carried in a reflow furnace;

FIG. 10 is a diagram illustrating a plane view of a wiring pattern formed on a front surface of an electronic circuit board according to a first modification;

FIG. 11 is a diagram illustrating a plane view of a wiring pattern formed on a front surface of an electronic circuit board according to a second modification;

FIG. 12 is a diagram illustrating a plane view of a wiring pattern formed on a front surface of an electronic circuit board according to a third modification;

FIG. 13 is a diagram illustrating a plane view of a wiring pattern formed on a front surface of an electronic circuit board according to a fourth modification; and

FIG. 14 is a diagram illustrating a plane view of a wiring pattern formed on a front surface of an electronic circuit board according to a fifth modification.

### DETAILED DESCRIPTION OF THE EXEMPLARY EMBODIMENTS

### First Embodiment

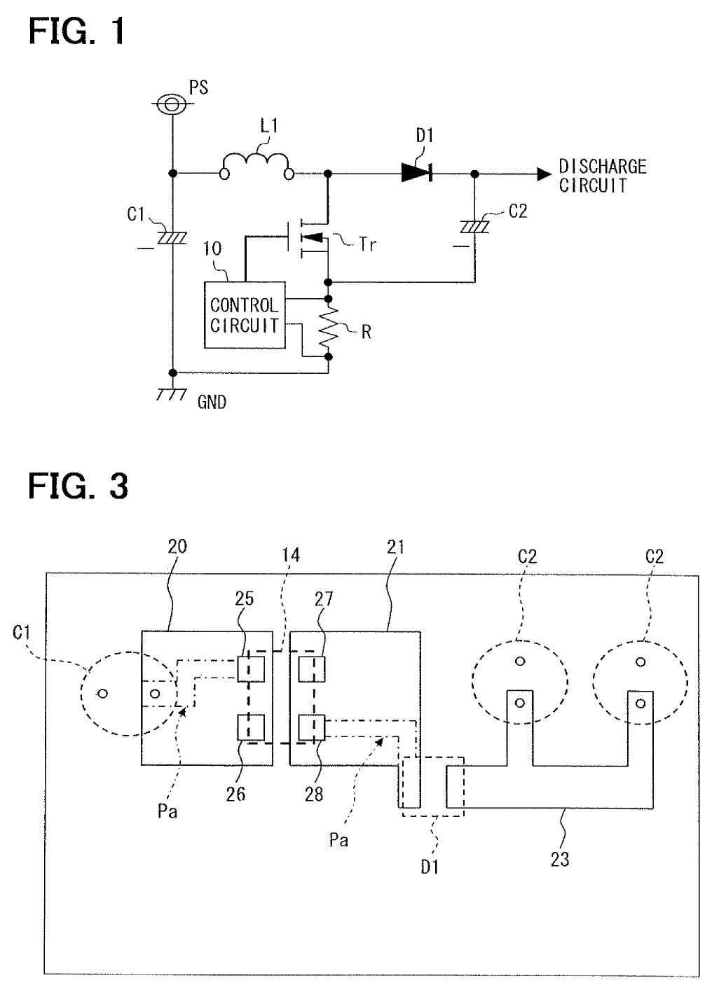

An electronic circuit board according to a first embodiment of the present invention will be described with reference to FIG. 1 to FIG. 5. The electronic circuit board can be used as a circuit board of an injector driving circuit in an electronic circuit device used for a diesel engine or a direct gasoline-injection engine, for example. The electronic circuit board can also be used as any circuit board having a surface mount device including a built-in coil and can restrict a reduction in quality of soldering of the surface mount device by a reflow heating.

First, an injector driving circuit formed in the electronic circuit board will be described. The injector driving circuit includes a boost circuit including a DC-DC converter and a smoothing capacitor C2 for storing a voltage boosted by the DC-DC converter. As illustrated in FIG. 1, the boost circuit further includes a capacitor C1 coupled with a power source (PS). The capacitor C1 is provided for restricting a fluctuation in a power supply voltage when a high current flows to the DC-DC converter.

The DC-DC converter includes a power choke coil L1, a switching element Tr, a resistor R, a rectifier diode D1, and a control circuit 10. The voltage boosted by the DC-DC converter is stored in the smoothing capacitor C2. In the present embodiment, when a discharge circuit is activated in a state where a high voltage is stored in the smoothing capacitor C2, a high current is supplied from the smoothing capacitor C2 to an injector (not shown) through the discharge circuit.

An operation of the boost circuit will be described. When the control circuit 10 turns on the switching element Tr, electric current flows through the power choke coil L1, the switching element Tr, and the resistor R. If the control circuit 10 determines that electric current flowing in the resistor R reaches a predetermined value based on a terminal voltage of the resistor R, the control circuit 10 turns off the switching element Tr. Then, a magnetic energy stored in the power choke coil L1 due to electric current supplied until the switching element Tr is turned off is discharged as an electric energy, and the smoothing capacitor C2 is charged through the rectifier diode D1.

The control circuit 10 monitors a voltage of the smoothing capacitor C2 using a voltage detecting circuit (not shown). The control circuit 10 controls an on/off state of the switching element Tr so that the voltage of the smoothing capacitor C2 corresponds to a target voltage.

The boost circuit is required to stably supply a high current to the injector when a frequency of discharge from the smoothing capacitor C2 increases, for example, due to increasing of an engine rotation speed. Thus, the DC-DC converter includes the power choke coil L1 that is difficult to be saturated magnetically even when a high current is supplied and that has a high inductance. As a result, a dimension of the power choke coil L1 becomes large.

Since the power choke coil L1 has a large dimension and has a high heat capacity due to a core and a coil arranged therein, the power choke coil L1 is soldered on a substrate by a reflow heating as a surface mount device. However, since the power choke coil L1 has the high heat capacity, a temperature of a terminal of the surface mount device having the built-in power choke coil L1 is difficult to increase sufficiently only by the reflow heating. Thus, a quality of the soldering may be reduced.

Therefore, in the present embodiment, a configuration of the electronic circuit board is designed so that the reduction in the quality of the soldering including insufficient solder wettability and insufficient solder melting is restricted even when the surface mount device having the built-in power choke coil L1 is soldered on the substrate by the reflow heating.

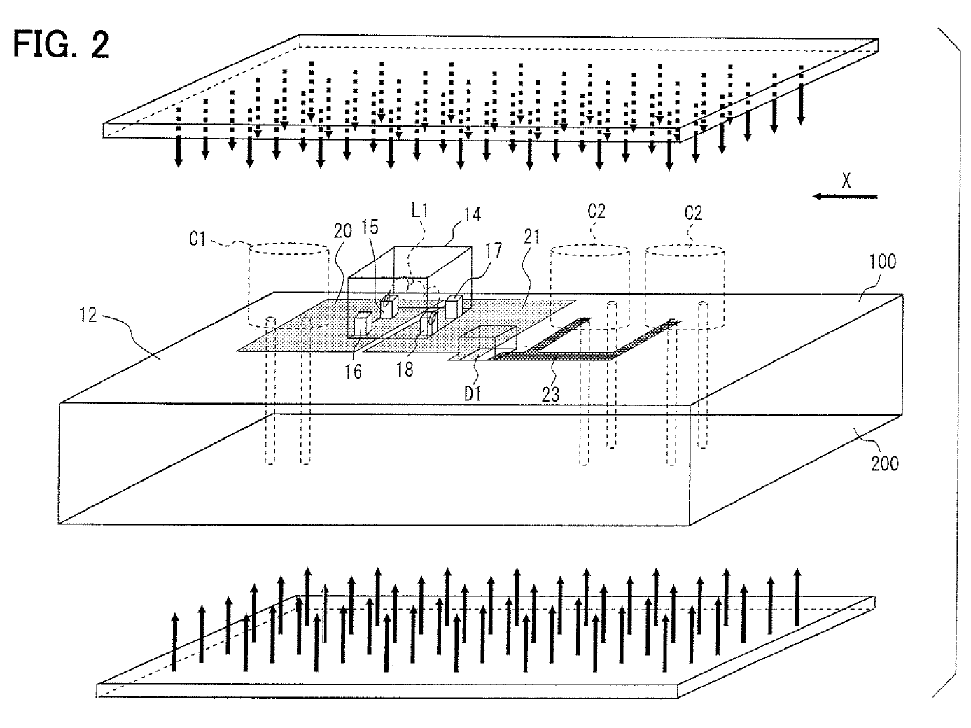

As illustrated in FIG. 2 and FIG. 3, the boost circuit is mounted on a substrate 12. The power choke coil L1 is built in a surface mount device 14. Thus, the surface mount device 14 has a heat capacity higher than other device such as the capacitors C1 and C2 and the rectifier diode D1. At a time when the surface mount device 14 is soldered by the reflow heating, the capacitors C1 and C2 each configured as a through-hole mount device are not mounted on the substrate 12. Thus, in FIG. 2, the capacitors C1 and C2 are illustrated in dashed lines. In FIG. 2 and FIG. 6 to FIG. 9, in order to describe a configuration of the electronic circuit board clearly, the electronic circuit board is schematically illustrated in such a manner that a thickness of the electronic circuit board is very large. In FIG. 3, the surface mount device 14, the rectifier diode D1, and the capacitors C1 and C2 are illustrated in dashed lines. As illustrated in FIG. 2 and FIG. 3, one terminal of the capacitor C1 and one terminal of the surface mount device 14 having the built-in power choke coil L1 are coupled with a first pattern 20 having a large area. The first pattern 20 is made of a metal having a high thermal conductivity. For example, the first pattern 20 may be made of copper or aluminum. The first pattern 20 is coupled with the power source through a wire (not shown).

The surface mount device 14 has a first connecting terminal 15, a second connecting terminal 18, a first fixing terminal 16, and a second fixing terminal 17. The first fixing terminal 16 and the second fixing terminal 17 are configured to ensure a fixing of the surface mount device 14 to the substrate 12. The first connecting terminal 15 and the first fixing terminal 16 are coupled with the first pattern 20. A second pattern 21 having a large area is adjacent to the first pattern 20. The second connecting terminal 18 and the second fixing terminal 17 are coupled with the second pattern 21. The first fixing terminal 16 is electrically independent from the first connecting terminal 15, and the second fixing terminal 17 is electrically independent from the second connecting terminal 18. Thus, a problem does not arise even if the first connecting terminal 15 and the first fixing terminal 16 are soldered to the same first pattern 20 and the second connecting terminal 18 and the second fixing terminal 17 are soldered to the same second pattern 21. On the contrary, the area of the first pattern 20 can be increased when the first connecting terminal 15 and the first fixing terminal 16 are soldered to the same first pattern 20 and the area of the second pattern 21 can be increased when the second connecting terminal 18 and the second fixing terminal 17 are soldered to the same second pattern 21. Each of the first pattern 20 and the second pattern 21 is a solid pattern expanding without clearance.

Each of the first pattern 20 and the second pattern 21 is covered with a resist layer. The resist layer has openings at portions corresponding to a first connecting land 25 and a first fixing land 26 of the first pattern 20 and a second fixing land 27 and a second connecting land 28 of the second pattern 21. That is, portions of the first pattern 20 and the second pattern 21 exposed from the openings of the resist layer become the first connecting land 25, the first fixing land 26, the second fixing land 27, and the second connecting land 28. Thus, the lands 25 to 28 can be provided at any position of the first pattern 20 and the second pattern 21, and a freedom of design can be improved.

The lands 25 to 28 defined by the openings of the resist layer are applied with a solder paste. The solder paste is melted by the reflow heating, and thereby the first connecting terminals 15 is soldered with the first connecting land 25, the second connecting terminal 18 is soldered with the second connecting land 28, the first fixing terminal 16 is soldered with the first fixing land 26, and the second fixing terminal 17 is soldered with the second fixing land 27.

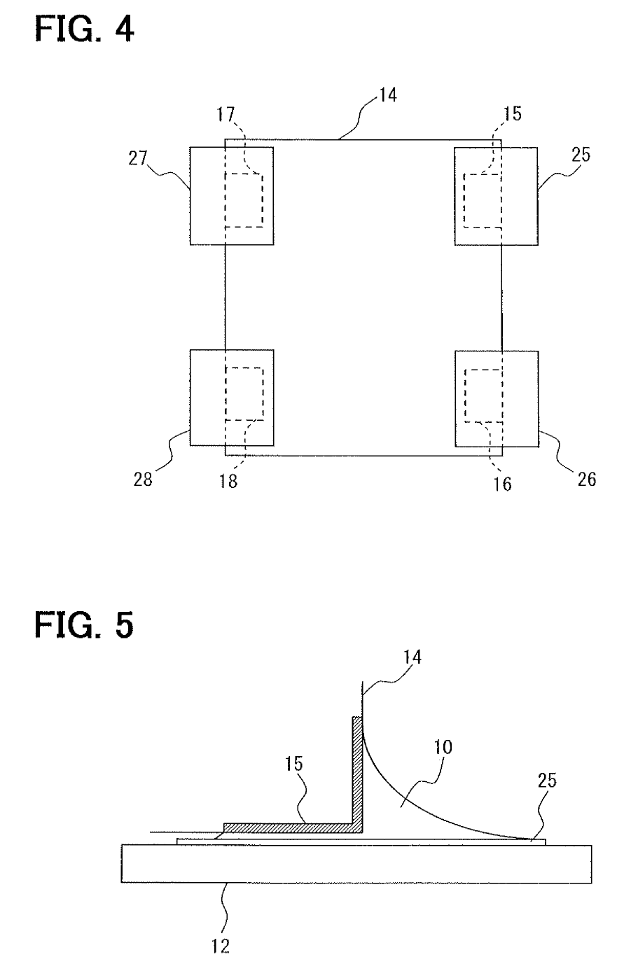

As illustrated in FIG. 4, on each of the lands 25 to 28, corresponding one of the terminals 15 to 18 is not disposed at a center portion but at a portion closer to the surface mount device 14. Thus, another portion of each of the lands 25 to 28 on which the corresponding one of terminals 15 to 18 is not directly disposed protrudes from a side surface of the surface mount device 14.

A side surface of each of the terminals 15 to 18 is located in the same plane as the side surface of the surface mount device 14. Furthermore, as illustrated in FIG. 5, each of the terminals 15 to 18 extends in a height direction of the surface mount device 14 so as to be exposed on the side surface of the surface mount device 14. Although only the first connecting terminal 15 is illustrated in FIG. 5, the second connecting terminal 18, the first fixing terminals 16 and the second fixing terminal 17 are disposed in the surface mount device 14 in a manner similar to the first connecting terminal 15.

As described above, a portion of each of the terminals 15 to 18 is exposed on the side surface of the surface mount device 14. In addition, each of the lands 25 to 28 protrudes from the side surface of the surface mount device 14. Thus, when the solder paste on each of the lands 25 to 28 is melted by the reflow heating, as shown in FIG. 5, a solder fillet is formed between each of the lands 25 to 28 and the exposed portion of corresponding one of the terminals 15 to 18. Thereby, a soldering strength of each of the terminals 15 to 18 to corresponding one of the lands 25 to 28 can be increased.

As illustrated in FIG. 2 to FIG. 4, if adjacent terminals in the surface mount device 14 are connected with hypothetical lines, the terminals 15 to 18 are located on respective vertices of a rectangle defined by the hypothetical lines. In addition, the first connecting terminal 15 and the second connecting terminal 18 are located at diagonally opposite corners of the rectangle and the first fixing terminal 16 and the second fixing terminal 17 are located on diagonally opposite corners of the rectangle.

The first connecting terminal 15 and the second connecting terminal 18 are coupled with respective end portions of power choke coil L1. The first fixing terminal 16 and the second fixing terminal 17 are provided for ensuring the fixing of the surface mount device 14 to the substrate 12 and are not coupled with the power choke coil L1. A heat capacity the first fixing terminal 16 is lower than a heat capacity of the first connecting terminal 15 and a heat capacity of the second fixing terminal 17 is lower than a heat capacity of the second connecting terminal 18. Thus, a temperature of the first fixing terminal 16 increases faster than a temperature of the first connecting terminal 15 and a temperature of the second fixing terminal 17 increases faster than the second connecting terminal 18. In such a case, the solder paste may be melted at different time between the first fixing terminal 16 and, the first connecting terminal 15 and between the second fixing terminal 17 and the second connecting terminal 18. Thus, the surface mount device 14 may be out of position due to a difference in a tensile force of the solder. As a result, the soldering of the first connecting terminal 15 and the first connecting land 25 and the soldering of the second connecting terminal 18 and the second connecting land 28 may be insufficient.

In the present embodiment, each of the terminals 15 to 18 is located at respective vertices of the rectangular, the first connecting terminal 15 and the second connecting terminal 18 are located at diagonally opposite corners of the rectangle, and the first fixing terminal 16 and the second fixing terminal 17 are located on diagonally opposite corners of the rectangle. In such a case, when the solder on the first fixing terminal 16 and the solder on the second fixing terminal 17 are melted, the tension difference of the solder is symmetrically applied to the surface mount device 14. Thus, even if the solder on the first connecting terminal 15 and the solder on the second connecting terminal 18 are melted at a time different from the solder on the first fixing terminal 16 and the solder on the second fixing terminal 17, a displacement of a mounting position of the surface mount device 14 can be restricted.

The rectifier diode D1 is disposed so as to straddle a portion of the second pattern 21 and one end portion of the wiring pattern 23. The rectifier diode D1 is configured as a surface mount device. In a manner similar to the surface mount device 14 having the built-in power choke coil L1, the rectifier diode D1 is soldered to the second pattern 21 and the wiring pattern 23 when the electronic circuit board is carried in the reflow furnace. On the other end portion of the wiring pattern 23, one terminal of the smoothing capacitor C2 is coupled so that the smoothing capacitor C2 is chargeable through the rectifier diode D1.

In the reflow furnace, as illustrated in FIG. 2, a plurality of nozzles is disposed on an upper plane and a lower plane. The nozzles blow out hot air as shown by arrows in FIG. 2. When the electronic circuit board is carried in the reflow furnace, a front surface 100 and a rear surface 200 of the substrate 12 are exposed to the hot air from the nozzles. Thereby, the solder applied to the front surface 100 and the rear surface 200 of the substrate 12 is melted and each component is soldered.

In the present embodiment, the surface mount device 14 has the built-in power choke coil L1. The first connecting terminal 15 of the surface mount device 14 is coupled with the first connecting land 25 formed on the substrate 12 as a part of the first pattern 20. In addition, the second connecting terminal 18 of the surface mount device 14 is coupled with the second connecting land 28 formed on the substrate 12 as a part of the second pattern 21.

In FIG. 3, a pattern area Pa determined in accordance with a current capacity for securing a required current value to be supplied to the power choke coil L1 is illustrated in dashed-dotted lines. The pattern area Pa is smaller than the area of the first pattern 20 and the area of the second pattern 21. Thus, in view of supplying the required current value, the first pattern 20 and the second pattern 21 are not required to have such large areas.

However, in the present embodiment, the inventor focuses on the high thermal conductivity of the metal pattern formed on the front surface 100 of the substrate 12, and the first pattern 20 and the second pattern 21 larger than the pattern area Pa determined in accordance with the current capacity for securing the required current value to be supplied to the power choke coil L1 are provided. Thereby, when the electronic circuit board is carried in the reflow furnace in a state where the surface mount device 14 is mounted on the substrate 12, the temperature of each of the lands 25 to 28 and the temperature of each of terminals 15 to 18 can be increased to a temperature at which the solder is melted sufficiently due to a heat collection effect and a heat conduction effect of the first pattern 20 and the second pattern 21. As a result, even when the surface mount device 14 having a high heat capacity is soldered on the substrate 12 by the reflow heating, a reduction in the quality of the soldering can be restricted.

As illustrated in FIG. 2, the electronic circuit board is carried in the reflow furnace in a carrying direction X in a state where the surface mount device 14 is mounted on the substrate 12, and the first pattern 20 and the second pattern 21 are arranged on the front surface 100 of the substrate 12 so as to be parallel to the carrying direction X. Thereby, when the electronic circuit board is carried in the reflow furnace, the temperature of each of the patterns 20, 21 can be increased efficiently.

The capacitors C1 and C2 are soldered on the substrate 12, for example, by a flow process, after the surface mount device 14 having the built-in the power choke coil L1 is soldered by the reflow heating.

### Second Embodiment

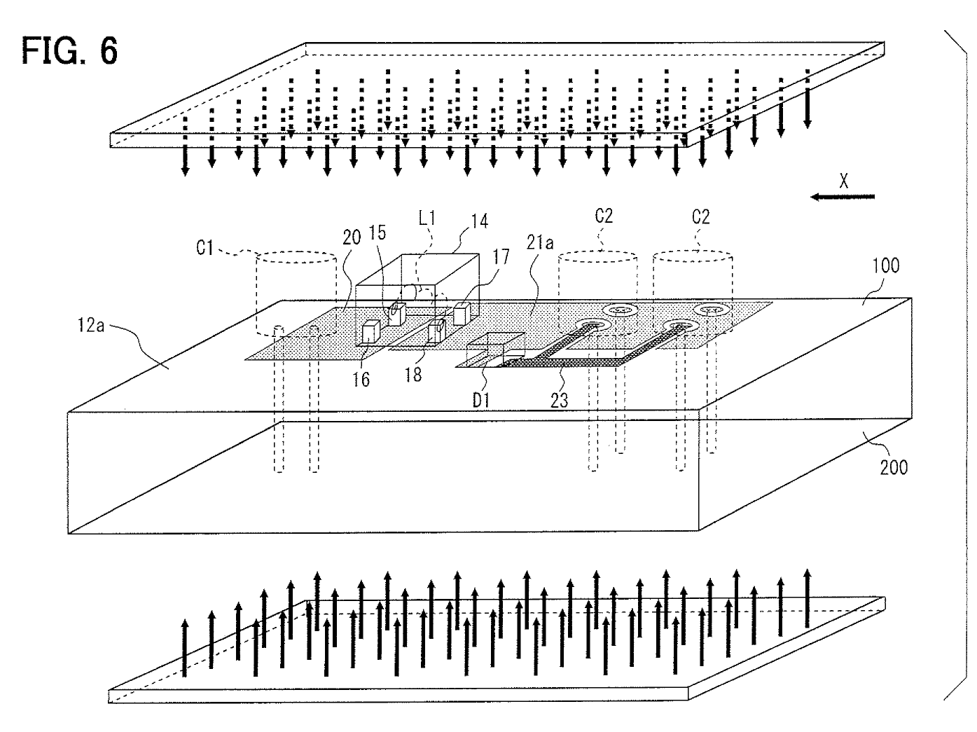

An electronic circuit board according to a second embodiment of the present invention will be described with reference to FIG. 6.

In the electronic circuit board, a second pattern 21a extends to a portion under the smoothing capacitors C2 arranged adjacent to the surface mount device 14 having the power choke coil L1 in a state where the second pattern 21 is insulated from the smoothing capacitors C2.

That is, the second pattern 21a extends to a mounting position of the smoothing capacitors C2. However, a slit is provided around each of the terminals of the smoothing capacitors C2 and the wiring pattern 23 coupled with the one terminal of each of the smoothing capacitors C2. Thereby, the terminals of the capacitors C2 and the wiring pattern 23 are insulated from the second pattern 21a.

The smoothing capacitors C2 are mounted on a substrate 12a after the surface mount device 14 having the power choke coil L1 is soldered by the reflow heating. In other words, when the surface mount device 14 is mounted on the substrate 12a by the reflow heating, the smoothing capacitors C2 as through-hole mount devices are not yet mounted on the substrate 12a. Thus, heat can be collected from the hot air in the reflow furnace using almost the whole surface of the second pattern 21a, and the temperature of each of the terminals 17 and 18 and the temperature of each of the lands 27 and 28 can be increased efficiently.

As region where the second patterns 21a is formed, a region under the smoothing capacitors C2 configured as through-hole mount devices is used. Thus, a front surface 100 of the substrate 12a can be used effectively and devices can be mounted on the substrate 12a in a high density.

### Third Embodiment

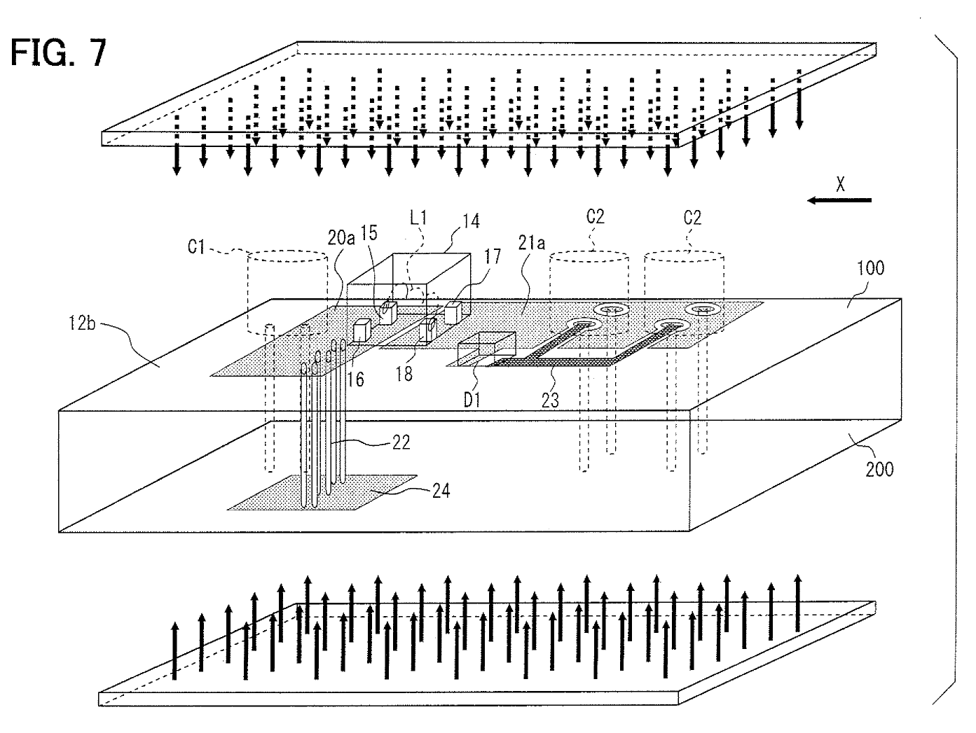

An electronic circuit board according to a third embodiment of the present invention will be described with reference to FIG. 7.

In the present embodiment, a first pattern 20a and a second pattern 21a are formed on a front surface 100 of a substrate 12b and a third pattern 24 is formed on a rear surface 200 of the substrate 12b. A plurality of via holes 22 filled with a metal material is provided in the substrate 12b so as to electrically couple the first pattern 20a and the third pattern 24. The metal material includes copper, for example.

The via holes 22 are provided in the electronic circuit board 12b by etching or drilling. Then, the metal material is deposited on an inner surface of the via holes 22 by electroless plating or electroplating. After that, the first pattern 20a is formed on the front surface 100 of the substrate 12b and the third pattern 24 is formed on the second surface 200 of the substrate 12b.

In the present case, heat can be collected using the third pattern 24 on the rear surface 200 of the substrate 12b in addition to the first pattern 20a on the front surface 100 of the substrate 12b. The heat collected by the third pattern 24 is transmitted to the first pattern 20a through the via holes 22. Thus, in the electronic circuit board, the temperature of each of the terminals 15 and 16 and the temperature of each of the lands 25 and 26 can be easily increased to a temperature at which the solder is melted sufficiently.

### Fourth Embodiment

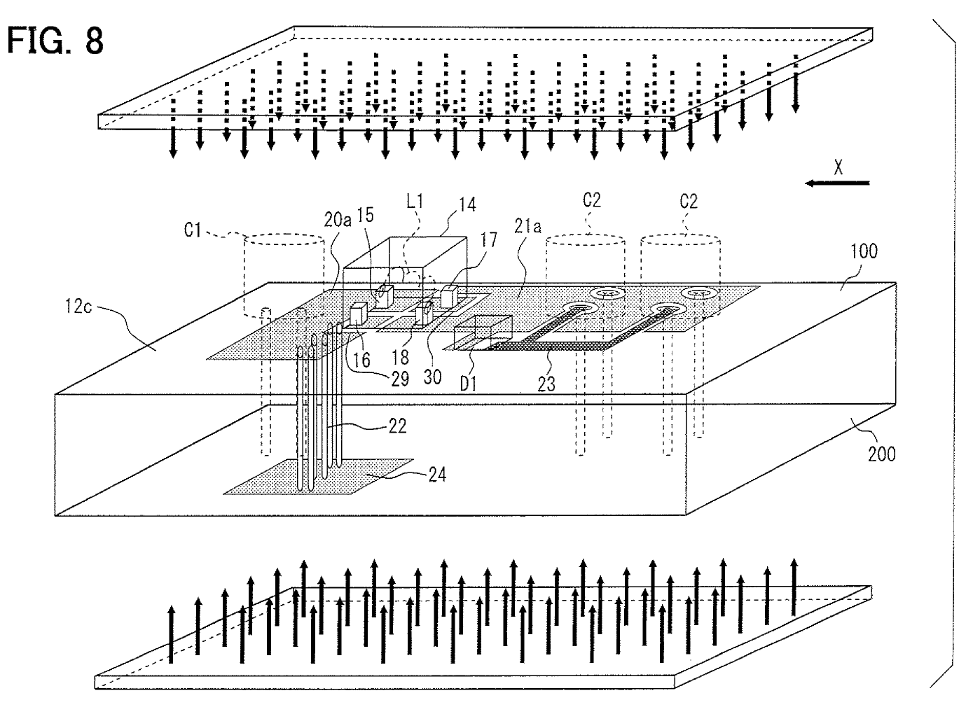

An electronic circuit board according to a fourth embodiment of the present invention will be described with reference to FIG. 8.

The first pattern 20a and the second pattern 21a are disposed on a front surface 100 of a substrate 12c and the third pattern 24 is disposed on a rear surface 200 of the substrate 12c. The first pattern 20a has a slit 29 around the first fixing land 26 on which the first fixing terminal 16 of the surface mount device 14 is soldered. The second pattern 21a has a slit 30 around the second fixing land 27 on which the second fixing terminal 17 of the surface mount device 14 is soldered.

That is, a portion of the first pattern 20a on which the first connecting terminal 15 is soldered and a portion of the first pattern 20a on which the first fixing terminal 16 is soldered are separated by the slit 29. In addition a portion of the second pattern 21a on which the second connecting terminal 18 is soldered and a portion of the second pattern 21a on which the second fixing terminal 17 is soldered are separated by the slit 30. An area of the portion of the first pattern 20a on which the first fixing terminal 16 is soldered is smaller than an area of the portion of the first pattern 20a on which the first connecting terminal 15 is soldered. An area of the portion of the second pattern 21a on which the second fixing terminal 17 is soldered is smaller than an area of the portion of the second pattern 21a on which the second connecting terminal 18 is soldered.

As described above, the first connecting terminal 15 and the second connecting terminal 18 are coupled with the power choke coil L1. Thus, the heat capacity of the first connecting terminal 15 and the second connecting terminal 18 is higher than the first fixing terminal 16 and the second fixing terminal 17. Thus, the temperature of the first connecting terminal 15 and the second connecting terminal 18 is difficult to increase compared with the first fixing terminal 16 and the second fixing terminal 17. In view of such a point, in the present embodiment, the area of the portion of the first pattern 20a on which the first fixing terminal 16 is soldered is set to be smaller than the area of the portion of the first pattern 20a on which the first connecting terminal 15 is soldered, and the area of the portion of the second pattern 21a on which the second fixing terminal 17 is soldered is set to be smaller than the area of the portion of the second pattern 21a on which the second connecting terminal 18 is soldered. Thereby, the heat collection effect of the first pattern 20a to the first fixing terminal 16 is set to be smaller than the heat collection effect of the first pattern 20a to the first connecting terminal 15, and the heat collection effect of the second pattern 21 a to the second fixing terminal 17 is set to be smaller than the heat collection effect of the second pattern 21a to the second connecting terminal 18. As a result, the difference between a time when the solder on the first connecting terminal 15 and the solder on the second connecting terminal 18 is melted and a time when the solder on the fixing terminals 16, 17 is melted can be reduced and the displacement of the surface mount device 14 can be reduced.

In the above-described embodiments, the connecting terminals 15 and 18 and the fixing terminals 16 and 17 are described as an example of terminals having different heat capacities. The terminals having different heat capacities are not limited to the above described example. For example, when transformers having different coil winding numbers are used as surface mount devices, an area of each portion of a pattern can be determined in accordance with the coil winding number of a connecting terminal connected with the portion of the pattern. Specifically, an area of a portion of a pattern on which a connecting terminal having a small winding number (i.e., a short coil length) and a low heat capacity may be smaller than an area of a portion of the pattern on which a connecting terminal having large winding number (i.e., long coil length) and a high heat capacity.

### Fifth Embodiment

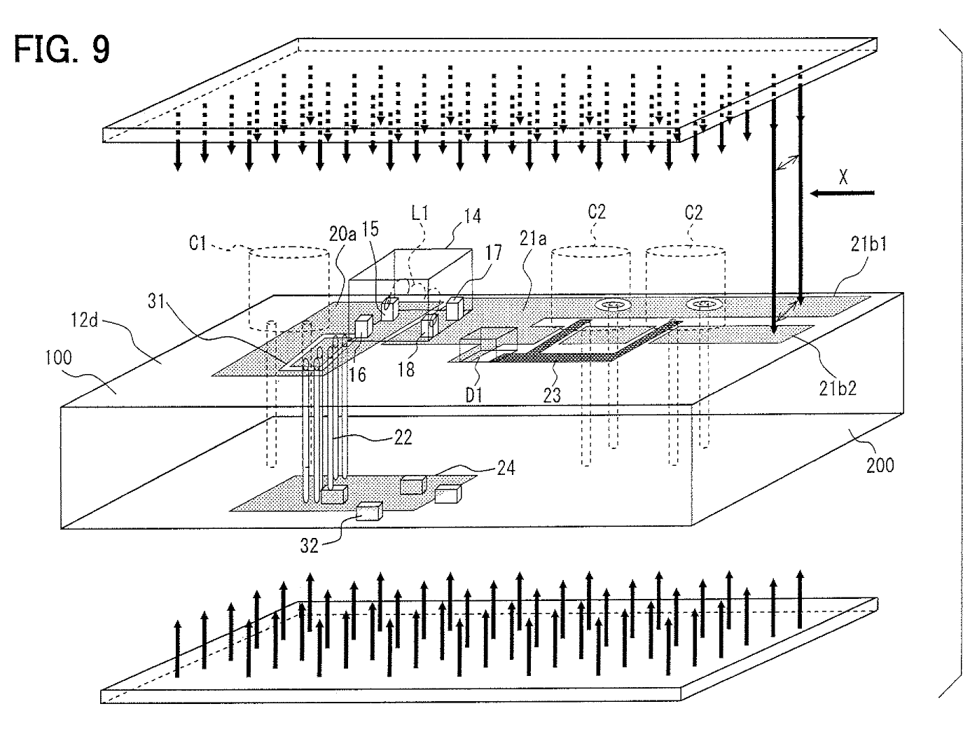

An electronic circuit board according to a fifth embodiment of the present invention will be described with reference to FIG. 9.

The first pattern 20a and the second pattern 21a are disposed on a front surface 100 of a substrate 12d and the third pattern 24 is disposed on a rear surface 200 of the substrate 12d. The via holes 22 filled with a metal material are provided in the substrate 12d. The metal material includes copper, for example. The via holes 22 electrically couple the first pattern 20a and the third pattern 24. The first pattern 20a has a slit 31 surrounding a front end portions of the via holes 22.

When the first pattern 20a has a slit 31, a portion of the first pattern 20a coupled with the via holes 22 and a portion of the first pattern 20a coupled with the first connecting terminal 15 of the surface mount device 14 can be electrically insulated from each other. In other words, the portion of the first pattern 20a coupled with the first connecting terminal 15 of the surface mount device 14 surrounds the via holes 22 through the slit 31 having a predetermined width. Thereby, the portion of the first pattern 20a coupled with the first connecting terminal 15 is electrically insulated from the third pattern 24.

However, in the first pattern 20a, the portion coupled with the first connecting terminals 15 of the surface mount device 14 and the portion coupled with the via holes 22 are adjacent to each other. Thus, the portion coupled with the first connecter terminals 15 and the portion coupled with the via holes 22 are thermally coupled with each other.

Therefore, it is not required for providing a pattern only for collecting heat on the rear surface 200 of the substrate 12d. Using the third pattern 24 for configurating other circuit, a temperature of the first pattern 20a on the front surface 100 of the substrate 12d can be increased efficiently. As illustrated in FIG. 9, a plurality of circuit elements 32 for configurating the other circuit is coupled with the third pattern 24.

The second pattern 21a includes a first band section 21b1 and a second band section 21b2 arranged apart from the surface mount device 14.

Each of the band sections 21b1, 21b2 is arranged under the nozzles provided at the upper plane of the reflow furnace. Thus, a distance between the nozzles in a direction perpendicular to the carrying direction X is substantially the same as a distance between the first band section 21b1 and the second band section 21b2.

When the second pattern 21a is formed and is arranged in the above-described manner, the first band section 21b1 and the second band section 21b2 of the second pattern 21a are directly exposed to the hot air blowing from the nozzles. Thus, the second section 21a can be received heat of the hot air efficiently without increasing the area of the second pattern 21a excessively.

### Other Embodiments

Although the present invention has been fully described in connection with the exemplary embodiments thereof with reference to the accompanying drawings, it is to be noted that various changes and modifications will become apparent to those skilled in the art.

In the first to fifth embodiments, the surface mount device 14 includes two fixing terminals, that is, the first fixing terminal 16 and the second fixing terminal 17, as an example. The first fixing terminal 16 is soldered with the first fixing land 26 of the first pattern 20 and the second fixing terminal 17 is soldered with the second fixing land 27 of the second pattern 21. The number of fixing terminals may also be one or more than two. By providing at least one fixing terminal, the surface mount device 14 can be fixed to the substrate 12 with certainty using the fixing terminal in addition to the first connecting terminal 15 and the second connecting terminal 18.

In the first embodiment, the first pattern 20 and the second pattern 21 have similar shapes and similar areas. The shapes and the areas of the first pattern 20 and the second pattern 21 may be different from each other. In such a case, when the first pattern 20 and the second pattern 21 for the surface mount device 14 is disposed on substrate 12, a degree of freedom of arranging positions of the first pattern 20 and the second pattern 21 can be improved. Thus, even if a region where the first pattern 20 and the second pattern 21 can be arranged is limited due to adjacent wiring pattern and other device, the first pattern 20 and the second pattern 21 can be arranged on the substrate 12 while securing a required heat collection area by changing the shapes and the areas of the first pattern 20 and the second pattern 21.

In the first embodiment, each of the first pattern 20 and the second pattern 21 is the solid pattern expanding without clearance. When each of the first pattern 20 and the second pattern 21 is the solid pattern, the first pattern 20 and the second pattern 21 can be formed easily. Alternatively, the first pattern 20 and the second pattern 21 may have various shapes. Exemplary modifications of the first pattern 20 and the second pattern 21 will be described below.

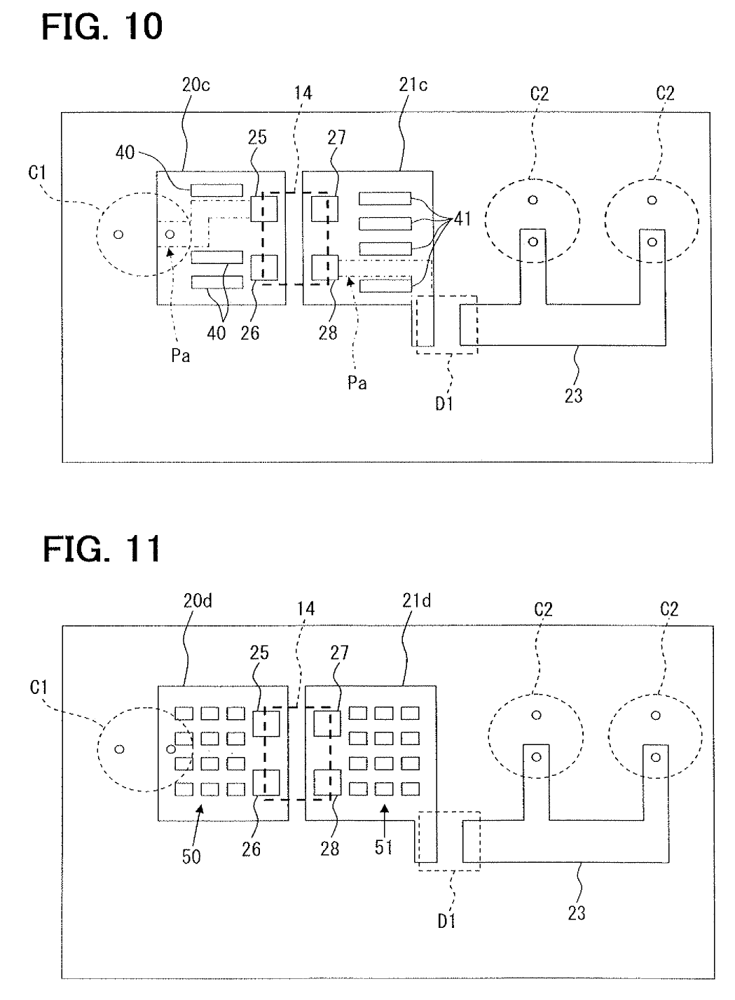

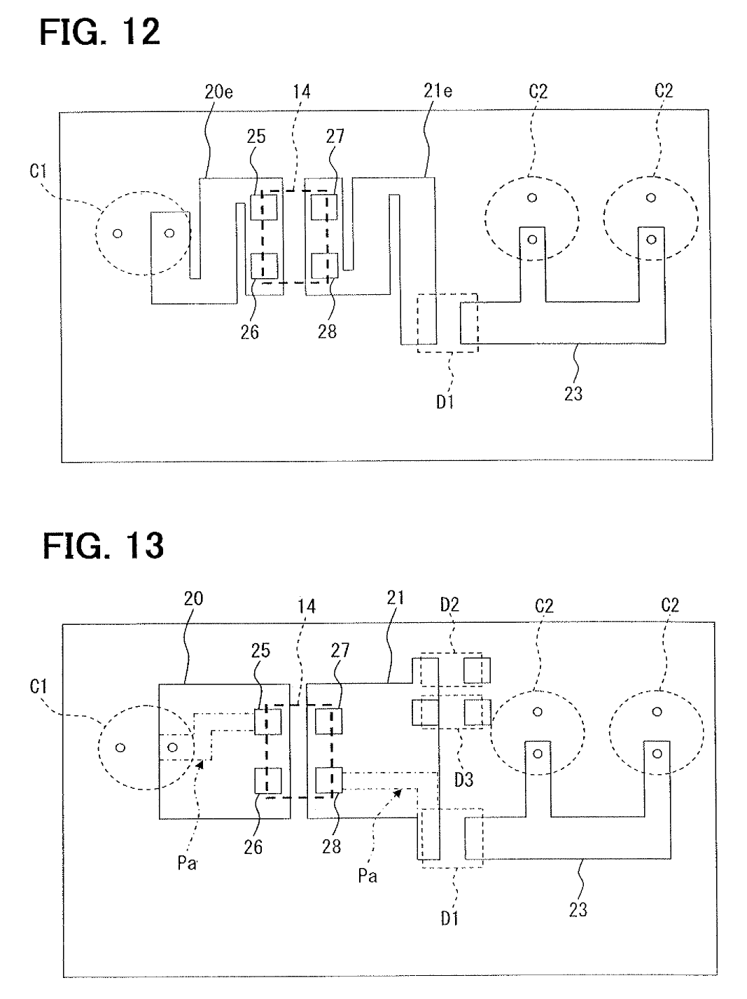

In a first modification illustrated in FIG. 10, a first pattern 20c has a plurality of regions 40 where a pattern is not formed, and a second pattern 21c has a plurality of regions 41 where a pattern is not formed. Each of the regions 40 and 41 has a rectangular shape. In a second modification illustrated in FIG. 11, a first pattern 20d has a plurality of regions 50 where a pattern is not formed, and the second pattern 21d has a plurality of regions 51 where a pattern is not formed. Each of the regions 50 and 51 are smaller than the regions 40 and 41 and is arranged in a lattice manner. In a third modification illustrated in FIG. 12, a first pattern 20e is formed into a zigzag shape and a second pattern 21e is formed into a zigzag shape.

The first patterns 20c to 20e and the second patterns 21c to 21e may have various shapes as long as each of the of the first patterns 20c to 20e and the second patterns 21c to 21e is larger than the pattern area Pa determined in accordance with the required current value. In addition, when the first patterns 20c to 20e and the second patterns 21c to 21e illustrated in FIG. 10 to FIG. 12 is used, even if there is a difference in linear expansion coefficient between the substrate 12 and patterns formed on the substrate 12 including the first patterns 20c to 20e and the second patterns 21 c to 21 e, a bias of the pattern with respect to the substrate 12 can be controlled. Thus, a deformation of the substrate 12 due to the difference in the linear expansion coefficient can be reduced.

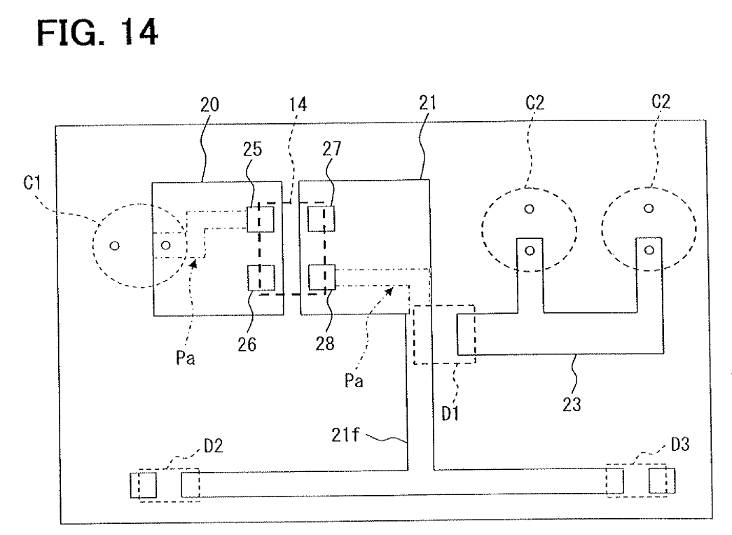

In the first embodiment, the second pattern 21 couples the power choke coil L1 built in the surface mount device 14 and the rectifier diode D1. The second pattern 21 may have a land to be coupled with other device including a dummy device. In a fourth modification illustrated in FIG. 13, using a land formed in the second pattern 21, other devices D2 and D3 are coupled in addition to the rectifier diode D1. Alternatively, as a fifth modification illustrated in FIG. 14, other devices D2 and D3 may be coupled with a land formed at an extending section 21f extending from the second pattern 21.

What is claimed is:

1. An electronic circuit board comprising:
a substrate having a first surface and a second surface opposing each other;
a plurality of devices mounted on the substrate, the plurality of devices including a surface mount device having a heat capacity higher than other device in the plurality of devices, the surface mount device including a terminal part; and
a pattern part disposed on the first surface of the substrate, the pattern part having an area larger than a pattern area determined in accordance with a current capacity for securing a required current value to be supplied to the surface mount device, the pattern part including a land part to which the terminal part of the surface mount device is coupled with a solder melted by heating in a reflow furnace.

2. The electronic circuit board according to claim 1, wherein
the surface mount device includes a coil.

3. The electronic circuit board according to claim 1, wherein:
the pattern part is covered with a resist layer;
the resist layer has an opening at a position corresponding to the land part; and
a portion of the pattern part exposed through the opening of the resist layer becomes the land part.

4. The electronic circuit board according to claim 1, wherein:
the terminal part includes a first connecting terminal, a second connecting terminal, and a fixing terminal;
the fixing terminal is configured to ensure a fixing of the surface mount device to the substrate;
the land part includes a first connecting land, a second connecting land, and a fixing land;
the first connecting terminal is soldered with the first connecting land;
the second connecting terminal is soldered with the second connecting land; and
the fixing terminal is soldered with the fixing land.

5. The electronic circuit board according to claim 2, wherein:
the terminal part includes a first connecting terminal, a second connecting terminal, a first fixing terminal, and a second fixing terminal;
the first connecting terminal and the second connecting terminal are coupled with respective end portions of the coil;
the first fixing terminal and the second fixing terminal are configured to ensure a fixing of the surface mount device to the substrate;
the land part includes a first connecting land, a second connecting land, a first fixing land, and a second fixing land;
the first connecting terminal is soldered with the first connecting land;
the second connecting terminal is soldered with the second connecting land;
the first fixing terminal is soldered with the first fixing land;
the second fixing terminal is soldered with the second fixing land;
the first connecting terminal, the second connecting terminal, the first fixing terminal, and the second fixing terminal are located on respective vertices of a rectangle defined by hypothetical lines connecting adjacent terminals among the first connecting terminal, the second connecting terminal, the first fixing terminal, and the second fixing terminal;
the first connecting terminal and the second connecting terminal are located at diagonally opposite corners of the rectangle; and
the first fixing terminal and the second fixing terminal are located at diagonally opposite corners of the rectangle.

6. The electronic circuit board according to claim 5, wherein:
the pattern part includes a first pattern and a second pattern;
the first pattern includes the first connecting land and the first fixing land; and
the second pattern includes the second connecting land and the second fixing land.

7. The electronic circuit board according to claim 1, wherein:
the terminal part has an exposed portion exposed on a side surface of the surface mount device; and
a solder fillet is formed between the exposed portion of the terminal part and the land part.

8. The electronic circuit board according to claim 1, wherein:
the substrate is carried in the reflow furnace in a carrying direction in a state where the surface mount device is disposed on the first surface of the substrate; and
the pattern part is disposed on the first surface of the substrate in a direction parallel to the carrying direction.

9. The electronic circuit board according to claim 8, wherein:
the reflow furnace includes a plurality of nozzles blowing hot air to a surface-side of the surface mount device; and
the pattern part is disposed on the first surface of the substrate in such a manner that the pattern part is directly exposed to the hot air when the substrate is carried in the reflow furnace.

10. The electronic circuit board according to claim 1, wherein:
the plurality of devices includes a through-hole mount device having a terminal part inserted in a through hole provided in the substrate;
the through-hole mount device is adjacent to the surface mount device;
the pattern part is insulated from the terminal part of the through-hole mount device; and
the pattern part extends to a region under the through-hole mount device.

11. The electronic circuit board according to claim 1, further comprising:
another pattern part disposed on the second surface of the substrate; and
a via hole filled with a metal material and thermally coupling the pattern part on the first surface of the substrate and the pattern part on the second surface of the substrate.

12. The electronic circuit board according to claim 11, wherein:
the pattern part on the first surface of the substrate surrounds the via hole through a clearance; and
the pattern part on the first surface of the substrate is electrically insulated from the metal material in the via hole.

13. The electronic circuit board according to claim 1, wherein:
the terminal part includes a plurality of terminals having different heat capacity;
the pattern part includes a plurality of pattern portions;
one of the plurality of terminals is coupled with corresponding one of the plurality of pattern portions having an area determined in accordance with the heat capacity of the one of the plurality of terminals.

14. The electronic circuit board according to claim 1, wherein
the pattern part is a solid pattern expanding without clearance.

15. The electronic circuit board according to claim 1, wherein
the pattern part has a region without a pattern.

16. The electronic circuit board according to claim 1, wherein
the pattern part has a zigzag shape.

17. An electronic control device comprising the electronic circuit board according to claim 1.
